(19) United States
(12) Patent Application Publication
(10) Pub. No.: US 2023/0164946 A1
(43) Pub. Date: May 25, 2023

(54) COLD PLATE MODULE

(71) Applicant: ACCTON TECHNOLOGY CORPORATION, HSINCHU (TW)

(72) Inventors: Yu Ting TSENG, Chiayi County (TW); Jih Che YEH, New Taipei City (TW)

(21) Appl. No.: 17/934,572

(22) Filed: Sep. 22, 2022

(30) Foreign Application Priority Data
Nov. 25, 2021 (TW) 110213961

(51) Int. Cl. H05K 7/20; H05K 7/14; G06F 1/18; G06F 1/20

(52) U.S. Cl. CPC H05K 7/20254; H05K 7/20272; H05K 7/1417; G06F 1/183; G06F 1/20; G06F 2200/201

(57) ABSTRACT

A cold plate module includes a cold plate, a structural piece and a plurality of first connecting pieces. The cold plate has a first surface and a second surface opposite to the first surface. The first surface is configured to abut against a heat source disposed on a main board. The structural piece has a third surface. The third surface is configured to abut against the second surface. The first connecting pieces are configured to penetrate through the structural piece and connect with the main board in order to fix the structural piece relative to the main board.

### RELATED APPLICATIONS

This application claims priority to Taiwanese Application Serial Number 110213961 filed Nov. 25, 2021, which is herein incorporated by reference.

### BACKGROUND

### Technical Field

The present disclosure relates to cold plate modules.

### Description of Related Art

With the improvement of living qualities nowadays, the demand of people for computer equipment has also been increasing. Correspondingly, in order to fulfill the increasing demand of consumers, the manufacturers have been working hard to improve the computer equipment.

Apart from improving the operational efficiency of computer equipment, for example, the approach to further strengthening the internal structure of computer equipment is undoubtedly an important issue which the industry highly concerns.

### SUMMARY

A technical aspect of the present disclosure is to provide a cold plate module, which can avoid from being deformed or damaged when experiencing an impact or a vibration.

According to an embodiment of the present disclosure, a cold plate module includes a cold plate, a structural piece and a plurality of first connecting pieces. The cold plate has a first surface and a second surface opposite to the first surface. The first surface is configured to abut against a heat source disposed on a main board. The structural piece has a third surface configured to abut against the second surface. The first connecting pieces are configured to penetrate through the structural piece and connect with the main board to fix the structural piece relative to the main board.

In one or more embodiments of the present disclosure, the structural piece includes a plate body, a plurality of connecting portions and a plurality of bending portions. The third surface is located on the plate body. Each of the connecting portions has a fourth surface configured to face to the main board. The first connecting pieces are configured to penetrate through the connecting portions and connect with the main board. The fourth surfaces and the third surface have a height difference. The bending portions are respectively connected between the plate body and a corresponding one of the connecting portions. The plate body is located between the bending portions.

In one or more embodiments of the present disclosure, the plate body, the connecting portions and the bending portions are an integrally formed structure.

In one or more embodiments of the present disclosure, the cold plate module further includes a plurality of elastic elements. The elastic elements are respectively and elastically connected between a corresponding one of the connecting portions and a corresponding one of the first connecting pieces.

In one or more embodiments of the present disclosure, the main board has a plurality of first screw holes. Each of the connecting portions has a plurality of first through holes corresponding to the first screw holes. Each of the first connecting pieces is a screw configured to penetrate through a corresponding one of the first through holes and couple with a corresponding one of the first screw holes.

In one or more embodiments of the present disclosure, the cold plate module further includes a plurality of second connecting pieces. The second connecting pieces are configured to penetrate through the plate body and connect with the cold plate to fix the plate body relative to the cold plate.

In one or more embodiments of the present disclosure, the cold plate has a plurality of second screw holes. The plate body has a plurality of second through holes corresponding to the second screw holes. Each of the second connecting pieces is a screw configured to penetrate through a corresponding one of the second through holes and couple with a corresponding one of the second screw holes.

In one or more embodiments of the present disclosure, the plate body has a plurality of third through holes. The cold plate includes a main body, an inlet port and an outlet port. The first surface and the second surface are located on the main body. The inlet port and the outlet port are respectively connected with the second surface and respectively penetrate through a corresponding one of the third through holes. The inlet port is configured to allow a cooling liquid to flow into the main body. The outlet port is configured to allow the cooling liquid to flow out from the main body. The cold plate module further includes a first connecting port and a second connecting port. The first connecting port is connected with the inlet port and is configured to connect to a cooling liquid supplying source. The second connecting port is connected with the outlet port and is configured to connect to a cooling liquid collector.

In one or more embodiments of the present disclosure, the plate body has a plurality of inner edges defining the third through holes. An outer edge of the inlet port and an outer edge of the outlet port are respectively and at least partially connected with a corresponding one of the inner edges.

In one or more embodiments of the present disclosure, the bending portions are separated from each other. The connecting portions are separated from each other.

According to an embodiment of the present disclosure, the cold plate module includes a cold plate, a bent structural piece and a plurality of first connecting pieces. The cold plate has a first surface and a second surface opposite to the first surface. The first surface is configured to abut against a heat source disposed on a main board. The bent structural piece has a third surface and a plurality of fourth surfaces. The third surface is located between the fourth surfaces. The third surface is configured to abut against the second surface. The fourth surfaces are configured to be closer to the main board than the third surface to the main board. The first connecting pieces are configured to penetrate through the fourth surfaces and connect with the main board to abut the cold plate against the heat source by the bent structural piece through fixing the bent structural piece relative to the main board.

In one or more embodiments of the present disclosure, the bent structural piece includes a plate body, a plurality of connecting portions and a plurality of bending portions. The third surface is located on the plate body. The fourth surfaces are respectively located on a corresponding one of the connecting portions. The fourth surfaces face to the main board. The first connecting pieces are configured to penetrate through the connecting portions. The bending portions are respectively connected between the plate body and a corresponding one of the connecting portions. The plate body is located between the bending portions.

In one or more embodiments of the present disclosure, the plate body, the connecting portions and the bending portions are integrally formed.

In one or more embodiments of the present disclosure, the cold plate module further includes a plurality of elastic elements. The elastic elements are respectively and elastically connected between a corresponding one of the connecting portions and a corresponding one of the first connecting pieces.

In one or more embodiments of the present disclosure, the main board has a plurality of first screw holes. Each of the connecting portions has a plurality of first through holes corresponding to the first screw holes. Each of the first connecting pieces is a screw configured to penetrate through a corresponding one of the first through holes and couple with a corresponding one of the first screw holes.

In one or more embodiments of the present disclosure, the cold plate module further includes a plurality of second connecting pieces. The second connecting pieces are configured to penetrate through the plate body and connect with the cold plate to fix the bent structural piece relative to the cold plate.

In one or more embodiments of the present disclosure, the cold plate has a plurality of second screw holes. The plate body has a plurality of second through holes corresponding to the second screw holes. Each of the second connecting pieces is a screw configured to penetrate through a corresponding one of the second through holes and couple with a corresponding one of the second screw holes.

In one or more embodiments of the present disclosure, the plate body has a plurality of third through holes. The cold plate includes a main body, an inlet port and an outlet port. The first surface and the second surface are located on the main body. The inlet port and the outlet port are respectively connected with the second surface. The inlet port and the outlet port respectively penetrate through a corresponding one of the third through holes. The inlet port is configured to allow a cooling liquid to flow into the main body. The outlet port is configured to allow the cooling liquid to flow out from the main body. The cold plate module further includes a first connecting port and a second connecting port. The first connecting port is connected with the inlet port and configured to connect to a cooling liquid supplying source. The second connecting port is connected with the outlet port and configured to connect to a cooling liquid collector.

In one or more embodiments of the present disclosure, the plate body has a plurality of inner edges defining the third through holes. An outer edge of the inlet port and an outer edge of the outlet port are respectively and at least partially connected with a corresponding one of the inner edges.

In one or more embodiments of the present disclosure, the bending portions are separated from each other. The connecting portions are separated from each other.

The above-mentioned embodiments of the present disclosure have at least the following advantages:

(1) As the bending portions are connected between the plate body and the connecting portions, the fourth surfaces of the connecting portions and the third surface of the structural piece have a height difference. In other words, the fourth surfaces of the connecting portions and the third surface of the structural piece are not located on the same height level. In this way, the structural piece has a reinforced moment of inertia. This means the structural piece has a good structural strength and is uneasy to be deformed.

(2) Since the structural piece has a good structural strength, when the cold plate module or the main board experiences an impact or a vibration, the structural piece is uneasy to be deformed and the structural piece can maintain its original shape. In this way, thanks to the structural strength of the structural piece, the cold plate abutting against the third surface of the structural piece will not be deformed under an impact or a vibration. Thus, the shape of the cold plate can be effectively maintained. In other words, the cold plate is uneasy to be damaged when the cold plate module or the main board experiences an impact or a vibration.

### BRIEF DESCRIPTION OF THE DRAWINGS

The disclosure can be more fully understood by reading the following detailed description of the embodiments, with reference made to the accompanying drawings as follows:

FIG. 1 is a schematic view of a cold plate module according to an embodiment of the present disclosure;

FIG. 2 is an exploded view of the cold plate module of FIG. 1;

FIG. 3 is a schematic bottom view of the structural piece of FIG. 1;

FIG. 4 is a cross-sectional view along the sectional line A-A of FIG. 1; and

FIG. 5 is a cross-sectional view along the sectional line B-B of FIG. 1.

### DETAILED DESCRIPTION

Drawings will be used below to disclose embodiments of the present disclosure. For the sake of clear illustration, many practical details will be explained together in the description below. However, it is appreciated that the practical details should not be used to limit the claimed scope. In other words, in some embodiments of the present disclosure, the practical details are not essential. Moreover, for the sake of drawing simplification, some customary structures and elements in the drawings will be schematically shown in a simplified way. Wherever possible, the same reference numbers are used in the drawings and the description to refer to the same or like parts.

Unless otherwise defined, all terms (including technical and scientific terms) used herein have the same meanings as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

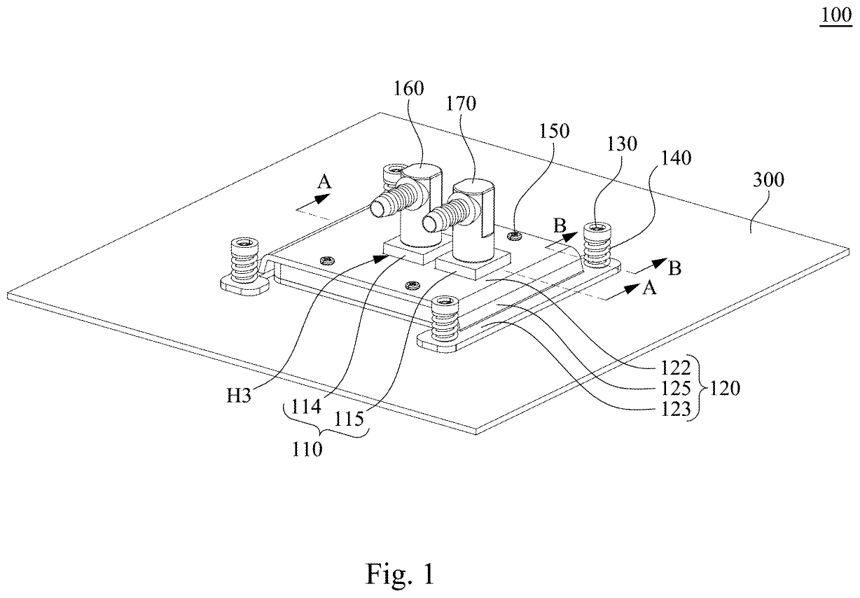

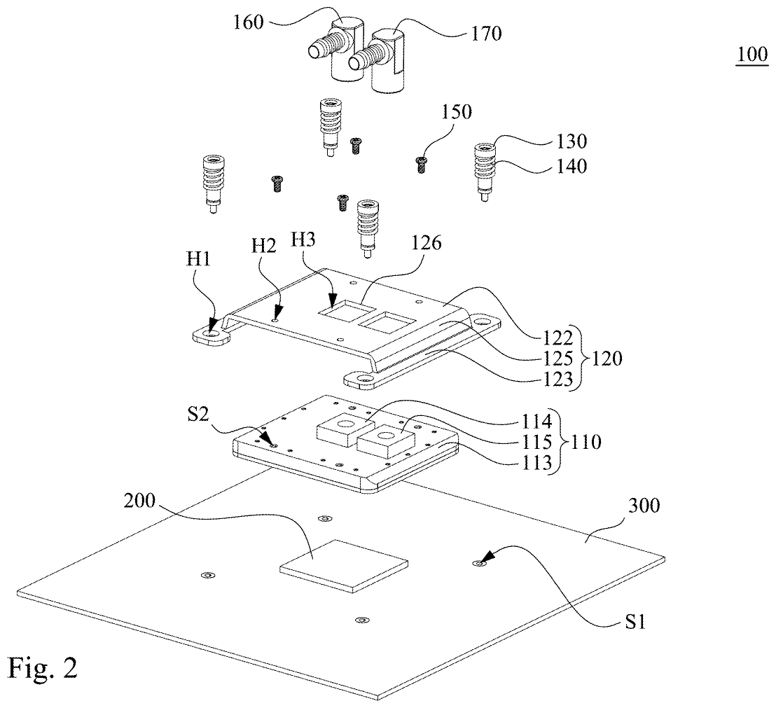

Reference is made to FIGS. 1-2. FIG. 1 is a schematic view of a cold plate module 100 according to an embodiment of the present disclosure. FIG. 2 is an exploded view of the cold plate module 100 of FIG. 1. In this embodiment, as shown in FIGS. 1-2, a cold plate module 100 includes a cold plate 110 (please see FIG. 2), a structural piece 120 and a plurality of first connecting pieces 130. The cold plate 110 is configured to abut against a heat source 200 (please see FIG. 2) in order to carry out heat dissipation to the heat source 200 by transferring the heat energy of the heat source 200 away. For example, the heat source 200 can be a chip or a die, which is disposed on a main board 300 of an electronic device. For example, the main board 300 can be an application specific integrated circuit (ASIC) board. However, this does not intend to limit the present disclosure. The structural piece 120 is configured to abut against and connect with the cold plate 110. The first connecting pieces 130 penetrate through the structural piece 120 and connect with the main board 300, so as to firmly fix the structural piece 120 together with the cold plate 110 on the heat source 200. It is worth to note that, in this embodiment, the cold plate 110 is located between the structural piece 120 and the heat source 200, while the structural piece 120 and the cold plate 110 are detachable from each other.

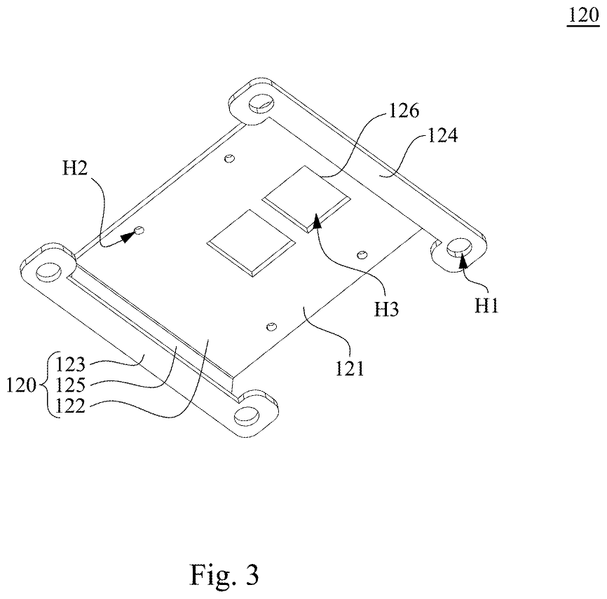

Reference is made to FIG. 3. FIG. 3 is a schematic bottom view of the structural piece 120 of FIG. 1. In this embodiment, as shown in FIGS. 1-3, the structural piece 120 includes a plate body 122, a plurality of connecting portions 123 and a plurality of bending portions 125. The structural piece 120 has a third surface 121. The third surface 121 is located on the plate body 122 and is configured to abut against the cold plate 110. Each of the connecting portions 123 has a fourth surface 124. The fourth surfaces 124 are configured to face to the main board 300. The first connecting pieces 130 are configured to penetrate through the connecting portions 123 of the structural piece 120 and connect with the main board 300, so as to firmly fix the structural piece 120 together with the cold plate 110 on the heat source 200. The bending portions 125 are respectively connected between the plate body 122 and the corresponding connecting portion 123. The plate body 122 is connected between the bending portions 125.

In practical applications, the plate body 122, the connecting portions 123 and the bending portions 125 are an integrally formed structure. Thus, the structural piece 120 has a better structural strength.

In this embodiment, as shown in FIGS. 1-3, the quantities of the bending portions 125 and the connecting portions 123 of the structural piece 120 are both two. The bending portions 125 and the connecting portions 123 are both located on two opposite sides of the plate body 122. In other words, the bending portions 125 are separated from each other, and the connecting portions 123 are also separated from each other.

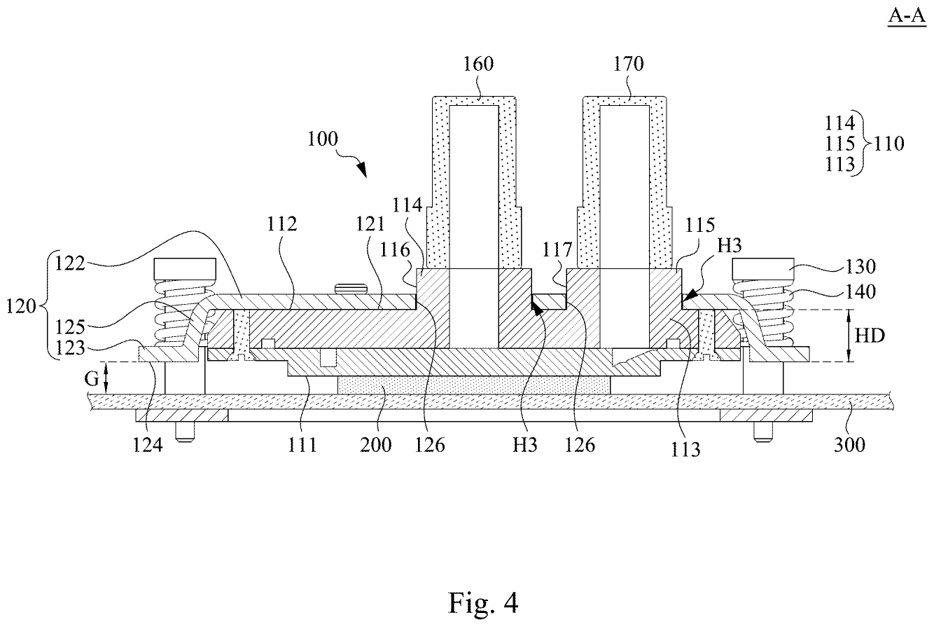

Reference is made to FIG. 4. FIG. 4 is a cross-sectional view along the sectional line A-A of FIG. 1. In this embodiment, as shown in FIG. 4, the cold plate 110 has a first surface 111 and a second surface 112 opposite to the first surface 111. The first surface 111 of the cold plate 110 is configured to abut against the heat source 200 disposed on the main board 300. The third surface 121 of the structural piece 120 is configured to abut against the second surface 112 of the cold plate 110. Thus, the cold plate 110 is located between the structural piece 120 and the heat source 200. The fourth surfaces 124 of the connecting portions 123 and the main board 300 have a gap G therebetween. Thus, the cold plate 110 can be tightly clamped between the structural piece 120 and the heat source 200. It is worth to note that, as the bending portions 125 are connected between the plate body 122 and the connecting portions 123, the fourth surfaces 124 of the connecting portions 123 and the third surface 121 of the structural piece 120 have a height difference HD. In other words, the fourth surfaces 124 of the connecting portions 123 and the third surface 121 of the structural piece 120 are not located on the same height level. In this way, the structural piece 120 has a reinforced moment of inertia. This means the structural piece 120 has a good structural strength and is uneasy to be deformed.

Since the structural piece 120 has a good structural strength, when the cold plate module 100 or the main board 300 experiences an impact or a vibration, the structural piece 120 is uneasy to be deformed and the structural piece 120 can maintain its original shape. In this way, due to the structural strength of the structural piece 120, the cold plate 110 abutting against the third surface 121 of the structural piece 120 will not be deformed under an impact or a vibration. Thus, the shape of the cold plate 110 can be effectively maintained. In other words, the cold plate 110 is uneasy to be damaged when the cold plate module 100 or the main board 300 experiences an impact or a vibration.

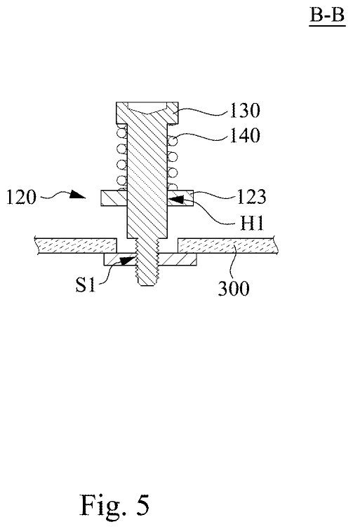

Reference is made to FIG. 5. FIG. 5 is a cross-sectional view along the sectional line B-B of FIG. 1. In this embodiment, as shown in FIG. 5, the first connecting pieces 130 are configured to penetrate through the connecting portions 123 of the structural piece 120 and connect with the main board 300 to fix the structural piece 120 relative to the main board 300. Thus, the structural piece 120 together with the cold plate 110 can be firmly fixed on the heat source 200.

To be more specific, as shown in FIGS. 2 and 5, the main board 300 has a plurality of first screw holes S1. As shown in FIGS. 2-3 and 5, each of the connecting portions 123 has a plurality of first through holes H1. The first through holes H1 of the connecting portions 123 correspond to the first screw holes S1 of the main board 300. Each of the first connecting pieces 130 can be a screw configured to penetrate through the corresponding first through hole H1 of the connecting portions 123 and couple with the corresponding first screw hole S1 of the main board 300, so as to fix the position of the structural piece 120 relative to the main board 300 in order to firmly fix the structural piece 120 together with the cold plate 110 on the heat source 200.

In addition, as shown in FIGS. 1-2 and 4-5, the cold plate module 100 further includes a plurality of elastic elements 140. The elastic elements 140 are respectively and elastically connected between the corresponding connecting portion 123 and the corresponding first connecting piece 130. In this way, when the structural piece 120 is fixed on the main board 300 by the first connecting pieces 130, the elastic elements 140 will be compressed, and the force that the cold plate 110 exerting on the heat source 200 from the structural piece 120 can be cushioned. Thus, the structural piece 120 is avoided from being crushed by the heat source 200 or the cold plate 110. In practical applications, each of the elastic elements 140 can be a spring. However, this does not intend to limit the present disclosure.

Moreover, as shown in FIGS. 1-2, the cold plate module 100 further includes a plurality of second connecting pieces 150. The second connecting pieces 150 are configured to penetrate through the plate body 122 of the structural piece 120 and connect with the cold plate 110 to fix the plate body 122 relative to the cold plate 110. This means the structural piece 120 is fixed on the cold plate 110, such that the third surface 121 of the structural piece 120 and the second surface 112 of the cold plate 110 abut against each other.

To be more specific, as shown in FIG. 2, the cold plate 110 has a plurality of second screw holes S2. As shown in FIGS. 2-3, the plate body 122 of the structural piece 120 has a plurality of second through holes H2. The second through holes H2 of the plate body 122 correspond to the second screw holes S2 of the cold plate 110. Each of the second connecting pieces 150 can be a screw configured to penetrate through the corresponding second through hole H2 of the plate body 122 and couple with the corresponding second screw hole S2 of the cold plate 110, so as to fix the structural piece 120 on the cold plate

Furthermore, as shown in FIGS. 1-4, the plate body 122 of the structural piece 120 has a plurality of third through holes H3. The cold plate 110 includes a main body 113, an inlet port 114 and an outlet port 115. The first surface 111 and the second surface 112 are located on the main body 113. The inlet port 114 and the outlet port 115 are respectively connected with the second surface 112 and respectively penetrate through the corresponding third through hole H3 of the plate body 122. The inlet port 114 is configured to allow a cooling liquid (not shown) to flow into the main body 113. The outlet port 115 is configured to allow the cooling liquid to flow out from the main body 113. The cold plate module 100 further includes a first connecting port 160 and a second connecting port 170. The first connecting port 160 is connected with the inlet port 114 and is configured to connect to a cooling liquid supplying source (not shown). The second connecting port 170 is connected with the outlet port 115 and is configured to connect to a cooling liquid collector (not shown).

During the operation of the cold plate module 100, the cooling liquid supplying source supplies the cooling liquid. The cooling liquid sequentially flows through the first connecting port 160 and the inlet port 114 and enters into the main body 113 of the cold plate 110. Since the first surface 111 located on the main body 113 abuts against the heat source 200, the heat energy of the heat source 200 can be transferred to the cooling liquid inside the main body 113, such that the cooling liquid is heated up. The heated cooling liquid then sequentially flows through the outlet port 115 and the second connecting port 170 and flows to the cooling liquid collector. For example, the heated cooling liquid collected by the cooling liquid collector is flowed back to the cooling liquid supplying source after treatment of cooling down.

On the other hand, moreover, as shown in FIGS. 2-4, the plate body 122 of the structural piece 120 has a plurality of inner edges 126. The inner edges 126 define the third through holes H3. As shown in FIG. 4, an outer edge 116 of the inlet port 114 and an outer edge 117 of the outlet port 115 of the cold plate 110 are respectively and at least partially connected with the corresponding inner edge 126. In this way, as the inlet port 114 and the outlet port 115 of the cold plate 110 abut against the inner edges 126 of the plate body 122, the relative position of the structural piece 120 and the cold plate 110 can be further secured.

In conclusion, the aforementioned embodiments of the present disclosure have at least the following advantages:

(1) As the bending portions are connected between the plate body and the connecting portions, the fourth surfaces of the connecting portions and the third surface of the structural piece have a height difference. In other words, the fourth surfaces of the connecting portions and the third surface of the structural piece are not located on the same height level. In this way, the structural piece has a reinforced moment of inertia. This means the structural piece has a good structural strength and is uneasy to be deformed.

(2) Since the structural piece has a good structural strength, when the cold plate module or the main board experiences an impact or a vibration, the structural piece is uneasy to be deformed and the structural piece can maintain its original shape. In this way, thanks to the structural strength of the structural piece, the cold plate abutting against the third surface of the structural piece will not be deformed under an impact or a vibration. Thus, the shape of the cold plate can be effectively maintained. In other words, the cold plate is uneasy to be damaged when the cold plate module or the main board experiences an impact or a vibration.

Although the present disclosure has been described in considerable detail with reference to certain embodiments thereof, other embodiments are possible. Therefore, the spirit and scope of the appended claims should not be limited to the description of the embodiments contained herein.

It will be apparent to the person having ordinary skill in the art that various modifications and variations can be made to the structure of the present disclosure without departing from the scope or spirit of the present disclosure. In view of the foregoing, it is intended that the present disclosure cover modifications and variations of the present disclosure provided they fall within the scope of the following claims.

What is claimed is:

1. A cold plate module, comprising:
a cold plate having a first surface and a second surface opposite to the first surface, the first surface being configured to abut against a heat source disposed on a main board;
a structural piece having a third surface configured to abut against the second surface; and
a plurality of first connecting pieces configured to penetrate through the structural piece and connect with the main board to fix the structural piece relative to the main board.

2. The cold plate module of claim 1, wherein the structural piece comprises:
a plate body, the third surface is located on the plate body;
a plurality of connecting portions, each of the connecting portions has a fourth surface configured to face to the main board, the first connecting pieces are configured to penetrate through the connecting portions and connect with the main board, the fourth surfaces and the third surface have a height difference; and
a plurality of bending portions respectively connected between the plate body and a corresponding one of the connecting portions, the plate body is located between the bending portions.

3. The cold plate module of claim 2, wherein the plate body, the connecting portions and the bending portions are an integrally formed structure.

4. The cold plate module of claim 2, further comprising a plurality of elastic elements respectively and elastically connected between a corresponding one of the connecting portions and a corresponding one of the first connecting pieces.

5. The cold plate module of claim 2, wherein the main board has a plurality of first screw holes, each of the connecting portions has a plurality of first through holes corresponding to the first screw holes, each of the first connecting pieces is a screw configured to penetrate through a corresponding one of the first through holes and couple with a corresponding one of the first screw holes.

6. The cold plate module of claim 2, further comprising a plurality of second connecting pieces configured to penetrate through the plate body and connect with the cold plate to fix the plate body relative to the cold plate.

7. The cold plate module of claim 6, wherein the cold plate has a plurality of second screw holes, the plate body has a plurality of second through holes corresponding to the second screw holes, each of the second connecting pieces is a screw configured to penetrate through a corresponding one of the second through holes and couple with a corresponding one of the second screw holes.

8. The cold plate module of claim 2, wherein the plate body has a plurality of third through holes, the cold plate comprises a main body, an inlet port and an outlet port, the first surface and the second surface are located on the main body, the inlet port and the outlet port are respectively connected with the second surface and respectively penetrate through a corresponding one of the third through holes, the inlet port is configured to allow a cooling liquid to flow into the main body, the outlet port is configured to allow the cooling liquid to flow out from the main body, the cold plate module further comprises a first connecting port and a second connecting port, the first connecting port is connected with the inlet port and configured to connect to a cooling liquid supplying source, the second connecting port is connected with the outlet port and configured to connect to a cooling liquid collector.

9. The cold plate module of claim 8, wherein the plate body has a plurality of inner edges defining the third through holes, an outer edge of the inlet port and an outer edge of the outlet port are respectively and at least partially connected with a corresponding one of the inner edges.

10. The cold plate module of claim 2, wherein the bending portions are separated from each other, the connecting portions are separated from each other.

11. A cold plate module, comprising:
a cold plate having a first surface and a second surface opposite to the first surface, the first surface being configured to abut against a heat source disposed on a main board;
a bent structural piece having a third surface and a plurality of fourth surfaces, the third surface being located between the fourth surfaces, the third surface being configured to abut against the second surface, the fourth surfaces being configured to be closer to the main board than the third surface to the main board; and
a plurality of first connecting pieces configured to penetrate through the fourth surfaces and connect with the main board to abut the cold plate against the heat source by the bent structural piece through fixing the bent structural piece relative to the main board.

12. The cold plate module of claim 11, wherein the bent structural piece comprises:
a plate body, the third surface is located on the plate body;
a plurality of connecting portions, the fourth surfaces are respectively located on a corresponding one of the connecting portions and face to the main board, the first connecting pieces are configured to penetrate through the connecting portions; and
a plurality of bending portions respectively connected between the plate body and a corresponding one of the connecting portions, the plate body is located between the bending portions.

13. The cold plate module of claim 12, wherein the plate body, the connecting portions and the bending portions are integrally formed.

14. The cold plate module of claim 12, further comprising a plurality of elastic elements respectively and elastically connected between a corresponding one of the connecting portions and a corresponding one of the first connecting pieces.

15. The cold plate module of claim 12, wherein the main board has a plurality of first screw holes, each of the connecting portions has a plurality of first through holes corresponding to the first screw holes, each of the first connecting pieces is a screw configured to penetrate through a corresponding one of the first through holes and couple with a corresponding one of the first screw holes.

16. The cold plate module of claim 12, further comprising a plurality of second connecting pieces configured to penetrate through the plate body and connect with the cold plate to fix the bent structural piece relative to the cold plate.

17. The cold plate module of claim 16, wherein the cold plate has a plurality of second screw holes, the plate body has a plurality of second through holes corresponding to the second screw holes, each of the second connecting pieces is a screw configured to penetrate through a corresponding one of the second through holes and couple with a corresponding one of the second screw holes.

18. The cold plate module of claim 12, wherein the plate body has a plurality of third through holes, the cold plate comprises a main body, an inlet port and an outlet port, the first surface and the second surface are located on the main body, the inlet port and the outlet port are respectively connected with the second surface and respectively penetrate through a corresponding one of the third through holes, the inlet port is configured to allow a cooling liquid to flow into the main body, the outlet port is configured to allow the cooling liquid to flow out from the main body, the cold plate module further comprises a first connecting port and a second connecting port, the first connecting port is connected with the inlet port and configured to connect to a cooling liquid supplying source, the second connecting port is connected with the outlet port and configured to connect to a cooling liquid collector.

19. The cold plate module of claim 18, wherein the plate body has a plurality of inner edges defining the third through holes, an outer edge of the inlet port and an outer edge of the outlet port are respectively and at least partially connected with a corresponding one of the inner edges.

20. The cold plate module of claim 12, wherein the bending portions are separated from each other, the connecting portions are separated from each other.
